(19) United States
(12) Patent Application Publication
(10) Pub. No.: US 2003/0139068 A1
(43) Pub. Date: Jul. 24, 2003

(54) Method of Illumination with linearly polarized laser radiation

(75) Inventors: Masanao Maruta, Hyogo (JP); Takeshi Iwamoto, Hyogo (JP)

Correspondence Address: McDERMOTT, WILL & EMERY, 600 13th Street, N.W, Washington, DC, 20005-3096, US

(73) Assignee: Mitsubishi Denki Kabushiki Kaisha

(21) Appl. No.: 10/189,527

(22) Filed: Jul. 8, 2002

(30) Foreign Application Priority Data
Jan. 8, 2002 (JP) 2002-001129 (P)

(51) Int. Cl. H01L 21/26

(52) U.S. Cl. 438/940; 438/795

(57) ABSTRACT

In the present laser illumination method, laser radiation can illuminate a Cu fuse layer in a direction traversing a longitudinal direction of the Cu fuse layer to allow the laser radiation to illuminate a single location continuously without dispersing its energy. As a result the fuse layer can effectively be heated and completely be cut.

### BACKGROUND OF THE INVENTION

1. Field of the Invention

The present invention relates generally to methods of illumination with laser radiation and particularly to those allowing a redundant circuit of a semiconductor memory device to provide repair by directing laser radiation to illuminate a fuse layer therewith to cut the fuse layer.

2. Description of the Background Art

In recent years semiconductor memory devices, LSI in particular, increasingly require an approach to address larger amounts of electric current and to address the issue a conventional Al interconnection is being shifted to a Cu interconnection. A SOC or other similar devices having a memory and a logic accommodated within a single chip are formed in a common process and to substitute a defective line of the memory portion with a redundant circuit a fuse layer is adopted and also for this fuse layer a conventional Al fuse is being shifted to a Cu fuse. Furthermore in the current fabrication process technology, with microfabrication-attributable defect density considered, a system previously incorporating a redundant circuit would be essential.

As described above, in logic LSI an increased amount of electric current is required, and to allow an increased, tolerable electric current of a Cu interconnection itself an increased area of a Cu interconnection layer, as seen in a planer view, is demanded. However, logic LSI can only have a limited area, as seen in the planer view, due to design. Thus, the Cu interconnection layer cannot have an area increased as desired, as seen in the planer view, and an approach is accordingly studied to increase the Cu interconnection layer in thickness, as seen in the direction of depth.

For a conventional Al interconnection a thickness of approximately 600 nm is adopted as seen in the direction of depth, and using the thickness for a Cu interconnection layer can contribute to an increased tolerable electric current. In recent years, as increased tolerable electric currents are increasingly demanded, a Cu interconnection layer having a thickness increased, as seen in the direction of depth, to approximately 1200 nm is demanded. This results in a fuse layer having a thickness, as seen in the direction of depth, of approximately 1000 nm to 1200 nm, which thickness would hardly be cut with conventional methods of illumination with laser radiation.

For a conventional method of illumination with laser radiation to blow a fuse layer it is important that laser radiation is absorbed to heat a fuse member, as seen in cross section, and in a short period of time a fuse layer is entirely, sufficiently heated to be close to its melting point. If the fuse layer is increased in thickness, as seen in the direction of depth, however, then before heat is conducted to heat the entirety of the fuse layer the fuse layer would have an explosion only at an upper portion thereof and as a result only the upper portion is exploded away while a lower portion of the fuse layer would remain disadvantageously.

More specifically, as shown in FIG. 6, if laser radiation 200 travels in a direction -Z, its electric field plane 200a travels, rotating about an axis Z in a plane X-Y. As a result, as shown in FIG. 7, when a Cu fuse layer 1 is seen on the side of a plane of illumination with laser radiation, with laser radiation 200 rotating while illuminating Cu fuse layer 1, the laser radiation 200 energy is distributed and thus provided illumination and energy is concentrated only at the center of rotation of laser radiation 200, and it can thus be understood that it fails to effectively heat the entirety of the fuse layer.

As a result, as shown in the FIG. 8 cross section, if laser radiation 200 is used to blow Cu fuse layer 1 covered with a barrier metal layer 2 and formed on a Si substrate 3 with an insulation film 4 posed therebetween, then Cu fuse layer 1 would have only an upper portion blown away while it has a lower portion remaining as a residue 50, which disadvantageously prevents switching to a redundant circuit.

### SUMMARY OF THE INVENTION

The present invention has been made to overcome the above disadvantage and it contemplates a method of illumination with laser radiation allowing a fuse layer to effectively absorb laser energy to heat the fuse layer to completely blow the fuse layer.

The present invention provides a method directing laser radiation to illuminate a fuse layer to be cut to control a redundant circuit provided internal to a semiconductor device, wherein the laser radiation illuminating the fuse layer is a linearly polarized laser radiation.

The foregoing and other objects, features, aspects and advantages of the present invention will become more apparent from the following detailed description of the present invention when taken in conjunction with the accompanying drawings.

### BRIEF DESCRIPTION OF THE DRAWINGS

In the drawings:

FIG. 1 represents linear polarization of laser radiation 100 of the present invention in an embodiment;

FIG. 2 schematically shows Cu fuse layer 1 in a laser illumination method of the present invention in an embodiment, as seen on the side of a plane of laser radiation;

FIG. 3 shows a structure of an end surface of Cu fuse layer 1 of the present invention in an embodiment before it is blown away;

FIG. 4 shows an end surface showing a residue in the present invention in an embodiment after blowing-away;

FIG. 5 represents a relationship between an angle of laser radiation 10 incident on Cu fuse layer 1 and reflectance thereof in the present embodiment in an embodiment;

FIG. 6 represents circular polarization of laser radiation in conventional art;

FIG. 7 schematically shows Cu fuse layer 1 in a laser illumination method of conventional art, as seen on the side of a plane of laser radiation; and

FIG. 8 shows an end surface showing a residue in a laser illumination method of conventional art after blowing-away.

### DESCRIPTION OF THE PREFERRED EMBODIMENTS

Hereinafter a laser illumination method of the present invention will be described in an embodiment with reference to the drawings. It should be noted that the fuse layer described hereinafter is cut by laser radiation to control a redundant circuit provided internal to a semiconductor device.

Laser Illumination Method

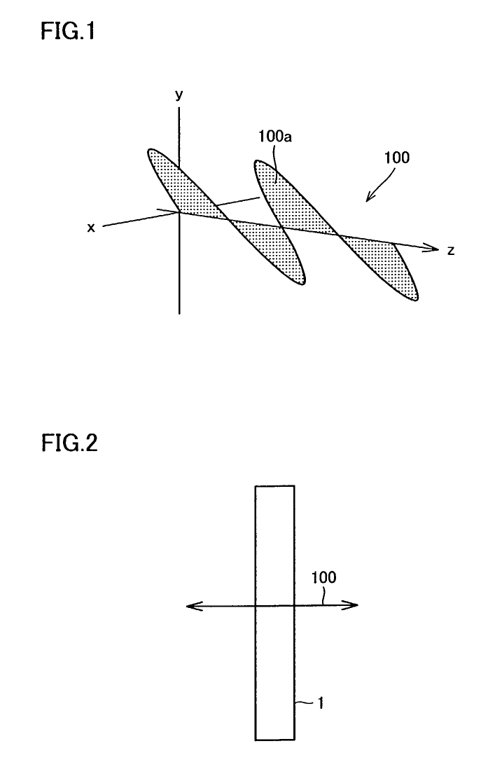

Initially reference will be made to FIGS. 1 and 2 to describe a method of directing laser radiation to illuminate Cu fuse layer 1 therewith in the present embodiment.

In the present embodiment, laser radiation 100 is linearly polarized, as shown in FIG. 1, and if laser radiation 100 travels in a direction -Z, then an electric field plane 100a travels with an axis Z as a center and it is also constantly directed in an invariable direction as seen in a plane X-Y.

If light propagates in direction -Z, an electric field E propagates with oscillation varying in magnitude and direction in a plane parallel to plane X-Y. Such propagation can be represented as follows:

E(x, y, z, t)=EOexp(I(wt−kz)) (1).

X and y components Ex and Ey of a plane wave of this expression can be represented in real function, as follows;

Ex=Ax·cos(wt−kz+φx) (2)

Ey=Ay·cos(wt−kz+φy) (3),

wherein

Ax: amplitude of x component

Ay: amplitude of y component

w: frequency

t: time

k: number of waves

φx: initial phase angle of x component

φy: initial phase angle of y component.

If a phase difference φ=φy−φy, then for linear polarization, for φ=2 mπ, wherein m is an integer, Ey=(Ay/Ax) Ex, or for φ=(2 m+1)π, wherein m is an integer, Ey=−(Ay/Ax) Ex.

As a result, as shown in FIG. 1, oscillation can be provided at any position z along a straight line. As a result, as shown in FIG. 2, by directing laser radiation 100 to Cu fuse layer 1 in a direction traversing a longitudinal direction of the layer, without having energy distributed the laser radiation can illuminate a single location continuously and thus effectively heat the fuse layer.

In directing laser radiation 100 to illuminate Cu fuse layer 1 so as to efficiently heat a shortest portion of Cu fuse layer 1 laser radiation 100 is adopted to have linear polarization in a direction traversing, preferably orthogonal to the longitudinal direction of Cu fuse layer 1.

Note that for conventional, circular polarization, if

Ax=Ay=A, π=±π/2+2 mπ, wherein m is an integer,

then,

Ex=A·cos(wt−kz+πx) (4)

Ey=A·cos(wt−kz+πx±π/2+2 mπ)=±A·sin(wt−kz+πx) (5).

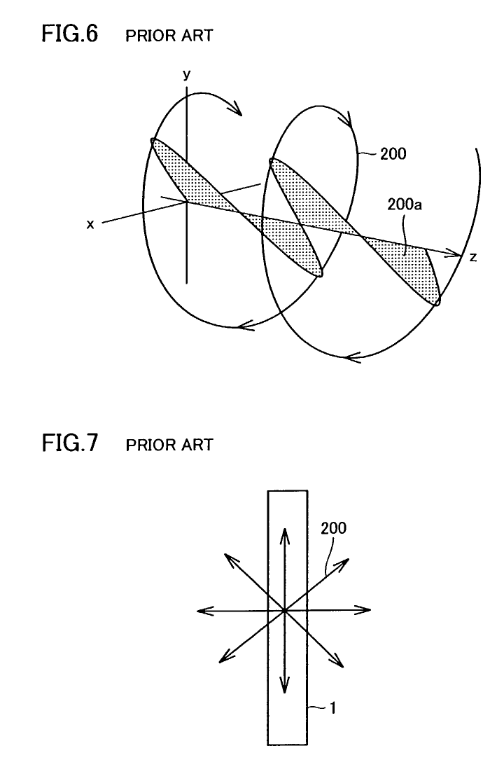

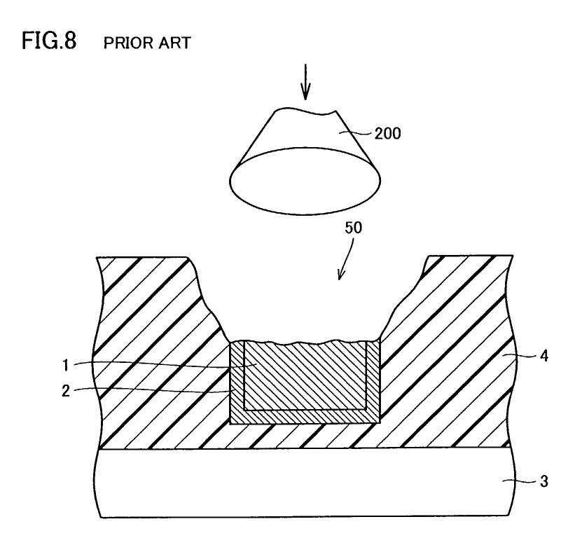

Thus from expressions (4) and (5) Ex2+Ey2=A2 is obtained, which indicates that at position z electric field vector E has an end having a locus of a circle having a radius A. As shown in FIG. 6, for circular polarization, if π=+π/2+2 mπ an electric field vector has a direction drawing a circle over time clockwise. As a result, as shown in FIG. 7, the laser radiation's electric field has a direction rotating through 360 degrees, while energy is distributed for illumination.

Embodiment

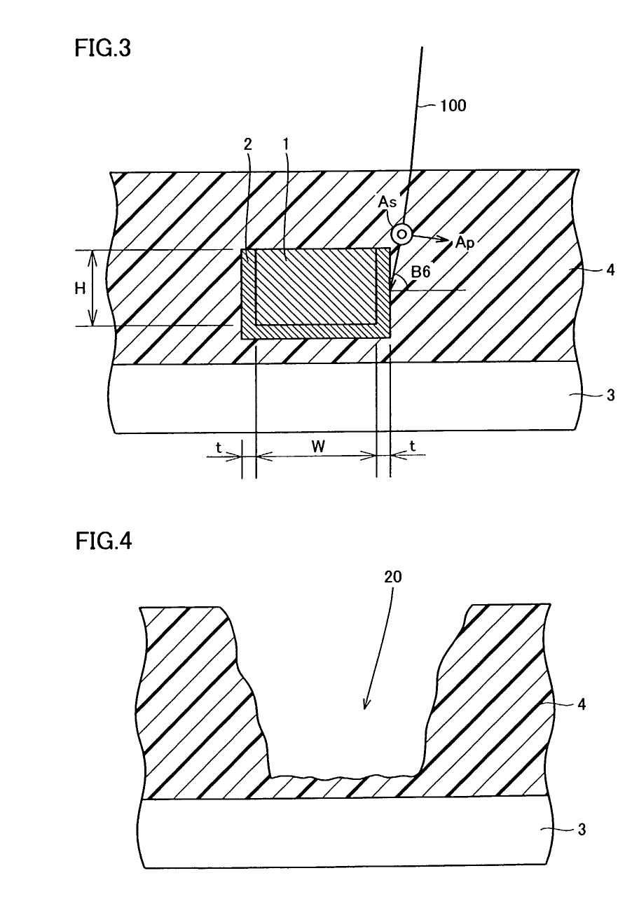

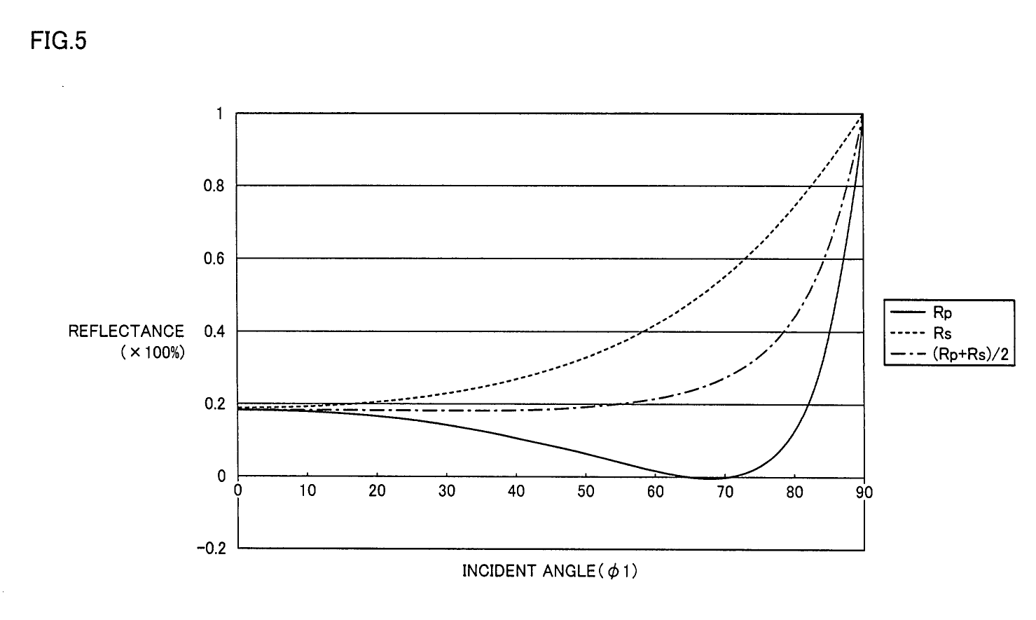

Hereinafter will be described the above laser illumination method employed to specifically blow a Cu fuse layer, with reference to FIGS. 3-5. Note that FIG. 3 shows a structure of an end surface of Cu fuse layer 1 before it is blown away, FIG. 4 shows an end surface showing a residue after blowing, and FIG. 5 represents a relationship between an angle (π1) of laser radiation 100 instead on Cu fuse layer 1 and reflectance.

With reference to FIG. 3, a Cu fuse layer 1 is formed on a Si substrate 3 with an interlayer insulation film 4 formed for example of SiO2, SiN or the like and posed therebetween. On Cu fuse layer 1 at side and bottom surfaces thereof a barrier metal layer 2 for example of TaN is formed to prevent diffusion of metal atoms from Cu fuse layer 1. Barrier metal layer 2 has a thickness t of approximately 40 angstroms, and Cu fuse layer 1 has a width W of approximately 1 μm and a thickness H, as seen in the direction of the depth of the substrate, of approximately 1000 nm to 1200 nm.

If the laser radiation 100 provides an electric field having an amplitude with a component Ap in a direction along an incident plane (a direction traversing Cu fuse layer 1) and a component As perpendicular to the incident plane, then, as shown in FIG. 1, when laser radiation 100 is directed to and thus illuminates Cu fuse layer 1, most of components are component Ap. By contrast, for circular polarization, other elliptical polarizations, and random (natural light), components Ap and As are generally equal in magnitude. Thus laser radiation only of component Ap can most efficiently enhance Cu fuse layer 1 and barrier metal layer 2. Laser radiation 100 herein used has a wavelength of approximately 1.0 to 1.3 micrometers (with a pulse width of approximately 5 ns to approximately 20 ns). Thus, the laser radiation can reliably cut Cu fuse layer 1 and barrier metal layer 2 to provide a residue 20, as shown in FIG. 4.

Herein, by an angle B6 of laser radiation 100 incident on barrier metal layer 2, barrier metal layer 2 provides a reflectance R represented in p and s waves, as follows:

Rp=tan²(π1−π2)tan²(π1+π2) (6)

Rs=sin²(π1−π2)sin²(π1+π2) (7),

wherein if π1 represents an angle of laser radiation 100 incident on barrier metal layer 2 from interlayer insulation film 4, π2 represents an angle of refraction, N1 represents an angle of refraction of SiO₂, having a value of approximately 1.45, and N2 represents an angle of refraction of a barrier metal layer (formed representatively of TaN), having a value of 4.88, then from the Snell's law, N1 sin π1=N2 sin π2, and expressions (6) and (7) a relationship between an incident angle and a reflectance can be obtained, as shown in FIG. 5.

As shown in FIG. 5, for an incident angle π1 of approximately 85 degrees, the s wave component's reflectance Rs is close to approximately 90%, whereas the p wave component's reflectance Rp is no more than approximately 30% and as a whole approximately 70% is transmitted. By contrast, for circular polarization, with p and s wave components are equal in amount, a reflectance of no more than 60% is thus provided, as shown in FIG. 5 by a graph of ((Rs+Rp)/2).

Thus, by providing laser radiation 100 so that its p wave component is increased, laser radiation 100 can be transmitted through barrier metal layer 2 to more effectively heat Cu fuse layer 1. It can be understood from FIG. 5 that reflectance Rp of the p wave component of laser radiation 100 can effectively be reduced simply by laser radiation 100 being incident on Cu fuse layer 1 at an upper plane 1a at angle π1 (B6) of approximately 70 to 80 degrees.

Function and Effect

Thus in the laser illumination method in the present embodiment when linearly polarized laser radiation is used to illuminate Cu fuse layer 1 with laser radiation 100 the laser radiation can illuminate a single location continuously without distributing its energy and it can thus effectively heat Cu fuse layer 1. As a result, as shown in FIG. 4, Cu fuse layer 1 can be heated instantly from the top plane through the bottom plane and as a result Cu fuse layer 1 can be cut completely.

It should be noted that while in the above embodiment the fuse layer is a Cu fuse layer, the present invention can provide a similar function and effect for a fuse layer formed of Al, AlCu, W or any other similar metal.

Thus, when linearly polarized laser radiation is used to illuminate a fuse layer, without having energy distributed it can illuminate a single location continuously to effectively heat the fuse layer. Consequently, the fuse layer can be heated instantly from the top plane through the bottom plane and as a result the fuse layer can be cut completely.

Furthermore in the above laser illumination method the laser radiation illuminates the fuse layer such that its linear polarization has a direction preferably traversing, more preferably orthogonal to a longitudinal direction of the fuse layer. The laser radiation can thus heat the fuse layer efficiently at a shortest portion thereof and thus cut the fuse layer more reliably.

Furthermore in the above laser illumination method preferably the laser radiation is incident on the fuse layer for illumination at an angle of 70 to 85 degrees relative to a top plane of the fuse layer. Thus, if the fuse layer has a side surface with a barrier metal layer formed thereon the barrier metal layer provides minimized reflection of the laser radiation. Consequently the laser radiation can be transmitted through the barrier metal layer and effectively illuminate the fuse layer to efficiently heat the fuse layer and thus more reliably cut the fuse layer.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of directing laser radiation to illuminate a fuse layer to be cut by laser radiation to control a redundant circuit provided internal to a semiconductor device, said laser radiation being linearly polarized laser radiation.

2. The method according to claim 1, wherein said laser radiation illuminates said fuse layer such that said laser radiation has linear polarization in a direction traversing a longitudinal direction of said fuse layer.

3. The method according to claim 2, wherein said laser radiation illuminates said fuse layer such that said laser radiation has linear polarization in a direction orthogonal to a longitudinal direction of said fuse layer.

4. The method according to claim 1, wherein said laser radiation is incident on said fuse layer at an angle of 70 to 85 degrees relative to a top plane of said fuse layer.
